(19) United States
(12) Patent Application Publication
(10) Pub. No.: US 2025/0008829 A1
(43) Pub. Date: Jan. 2, 2025

(54) DISPLAY APPARATUS

(71) Applicant: LG DISPLAY CO., LTD., Seoul (KR)

(72) Inventor: Sungsik SON, Gumi-si (KR)

(73) Assignee: LG DISPLAY CO., LTD., Seoul (KR)

(21) Appl. No.: 18/657,955

(22) Filed: May 8, 2024

(30) Foreign Application Priority Data
Jun. 27, 2023 (KR) 10-2023-0082555

(51) Int. Cl. H10K 59/90; H01L 25/18; H10K 59/80

(52) U.S. Cl. CPC H10K 59/90; H01L 25/18; H10K 59/80

(57) ABSTRACT

A display apparatus includes a support member; a display panel disposed on the support member; a printed circuit board electrically connected to one side of the display panel; and at least one circuit film having one side and the other side opposite to each other and electrically connected to the display panel and the printed circuit board, respectively, wherein at least a portion of the at least one circuit film is bent toward a rear surface of the display panel, wherein the support member includes at least one extension protruding from a side surface of the display panel and overlapping the circuit film on a rear surface of the circuit film.

### CROSS-REFERENCE TO RELATED APPLICATION

This application claims the priority of Korean Patent Application No. 10-2023-0082555 filed on Jun. 27, 2023, which is hereby incorporated by reference in its entirety.

### BACKGROUND

### Field of the Disclosure

The present disclosure relates to a display apparatus.

### Description of the Background

Contents described in this Background section simply provide background information about the present disclosure and do not constitute the prior art.

A display apparatus may include a display area that displays a screen and a non-display area disposed around the display area. The display apparatus requires not only a display panel to display the screen, but also various additional components such as a driver integrated circuit or a circuit board.

The additional components may be disposed in the non-display area, or various connection components such as a printed circuit board for connecting the additional components to the display panel may be disposed in the non-display area.

The non-display area in the display apparatus is referred to as a bezel area. When the bezel area becomes thinner, the user's immersion into the screen of the display area may increase.

Therefore, demand from a consumer for a display apparatus in which the bezel area size is reduced is increasing.

### SUMMARY

As the bezel of the display apparatus is thinner, the screen gets fuller, thereby increasing the sense of immersion of the user to the screen. Therefore, several studies are being conducted to reduce the bezel size. When the bezel size of the display apparatus is reduced, reliability of the display apparatus may be adversely affected, which may deteriorate performance of the display apparatus.

Accordingly, the present disclosure is directed to a display apparatus that substantially obviates one or more of problems due to limitations and disadvantages described above.

More specifically, the present disclosure is to provide a display apparatus that may improve reliability of the display apparatus and thus may reduce the bezel size of the display apparatus.

The present disclosure is not limited to the above-mentioned purpose. Other features and advantages of the present disclosure that are not mentioned may be understood based on following descriptions, and may be more clearly understood based on aspects of the present disclosure. Further, it will be easily understood that advantages of the present disclosure may be realized using means shown in the claims and combinations thereof.

Additional features and advantages of the disclosure will be set forth in the description which follows and in part will be apparent from the description, or may be learned by practice of the disclosure. Other advantages of the present disclosure will be realized and attained by the structure particularly pointed out in the written description and claims hereof as well as the appended drawings.

To achieve these and other advantages and in accordance with the present disclosure, as embodied and broadly described, a display apparatus includes a support member; a display panel disposed on the support member; a printed circuit board electrically connected to one side of the display panel; and at least one circuit film having one side and the other side opposite to each other and electrically connected to the display panel and the printed circuit board, respectively, wherein at least a portion of the at least one circuit film is bent toward a rear surface of the display panel, wherein the support member includes at least one extension protruding from a side surface of the display panel and overlapping the circuit film on a rear surface of the circuit film.

A display apparatus according to an aspect of the present disclosure may include a support member; a display panel disposed on the support member; a printed circuit board electrically connected to one side of the display panel; and at least one circuit film electrically connected to the printed circuit board, wherein a portion of the at least one circuit film is bent, wherein the support member overlaps at least a portion of the circuit film in a protruding area of the circuit film and includes at least one opening.

Specific details of other aspects are included in the detailed description and drawings.

According to an aspect of the present disclosure, the support member applied to the display apparatus supports the circuit film. Thus, the display apparatus with the reduced bezel size may be provided.

According to an aspect of the present disclosure, the support member applied to the display apparatus may include the extension, such that the bezel size of the display apparatus may be reduced, thereby improving the performance and/or reliability of the display apparatus.

According to an aspect of the present disclosure, the extension of the support member applied to the display apparatus includes the opening, such that damage to reliability of a bent portion of the support member may be prevented, thereby providing a low-power display apparatus with an improved lifespan.

Effects of the present disclosure are not limited to the effects mentioned above, and other effects not mentioned will be clearly understood by those skilled in the art from the descriptions below.

The purposes, solutions, and effects of the disclosure as described above does not specify essential features of claims. Thus, the scope of claims is not limited by the purposes, solutions, and effects of the disclosure as described above.

### BRIEF DESCRIPTION OF THE DRAWINGS

The accompanying drawings, which are included to provide a further understanding of the disclosure and are incorporated in and constitute a part of the disclosure, illustrate aspects of the disclosure and together with the description serve to explain the principle of the disclosure.

In the drawings:

FIG. 1 is a diagram showing a display apparatus according to an aspect of the present disclosure;

FIG. 2 is an exploded perspective view showing the display apparatus according to an aspect of the present disclosure;

FIG. 3 is a rear view of the display apparatus in a state in which some components in FIG. 2 are omitted;

FIG. 4 is a cross-sectional view taken along line A-A′ in FIG. 3;

FIG. 5 is a plan view showing a bent state of a support member in the display apparatus;

FIG. 6 is a plan view of the display apparatus according to an aspect of the present disclosure;

FIG. 7 is a diagram showing area A of FIG. 6 according to an aspect of the present disclosure;

FIG. 8 is a diagram showing area A of FIG. 6 according to another aspect of the present disclosure;

FIG. 9 is a diagram showing area A of FIG. 6 according to still another aspect of the present disclosure; and

FIG. 10 is a cross-sectional view of a display panel taken along line B-B′ in FIG. 1 according to an aspect of the present disclosure.

### DETAILED DESCRIPTION

Advantages and features of the present disclosure, and a method of achieving the advantages and features will become apparent with reference to aspects described later in detail together with the accompanying drawings. However, the present disclosure is not limited to the aspects as disclosed under, but may be implemented in various different forms. Thus, these aspects are set forth only to make the present disclosure complete, and to completely inform the scope of the present disclosure to those of ordinary skill in the technical field to which the present disclosure belongs, and the present disclosure is only defined by the scope of the claims.

A shape, a size, a ratio, an angle, a number, etc. disclosed in the drawings for illustrating aspects of the present disclosure are illustrative, and the present disclosure is not limited thereto. For simplicity and clarity of illustration, elements in the drawings are not necessarily drawn to scale. The same reference numbers in different drawings represent the same or similar elements, and as such perform similar functionality.

Further, descriptions and details of well-known steps and elements are omitted for simplicity of the description. Furthermore, in the following detailed description of the present disclosure, numerous specific details are set forth to provide a thorough understanding of the present disclosure. However, it will be understood that the present disclosure may be practiced without these specific details. In other instances, well-known methods, procedures, components, and circuits have not been described in detail so as not to unnecessarily obscure aspects of the present disclosure. Examples of various aspects are illustrated and described further below. It will be understood that the description herein is not intended to limit the claims to the specific aspects described. On the contrary, it is intended to cover alternatives, modifications, and equivalents as may be included within the spirit and scope of the present disclosure as defined by the appended claims.

The terminology used herein is directed to the purpose of describing particular aspects only and is not intended to be limiting of the present disclosure. As used herein, the singular constitutes “a” and “an” are intended to include the plural constitutes as well, unless the context clearly indicates otherwise. It will be further understood that the terms “comprise”, “comprising”, “include”, and “including” when used in this specification, specify the presence of the stated features, integers, operations, elements, and/or components, but do not preclude the presence or addition of one or more other features, integers, operations, elements, components, and/or portions thereof. As used herein, the term “and/or” includes any and all combinations of one or more of associated listed items. Expression such as “at least one of” when preceding a list of elements may modify the entire list of elements and may not modify the individual elements of the list. In interpretation of numerical values, an error or tolerance therein may occur even when there is no explicit description thereof.

In addition, it will also be understood that when a first element or layer is referred to as being present “on” a second element or layer, the first element may be disposed directly on the second element or may be disposed indirectly on the second element with a third element or layer being disposed between the first and second elements or layers.

It will be understood that when an element or layer is referred to as being “connected to”, or “connected to” another element or layer, it may be directly on, connected to, or connected to the other element or layer, or one or more intervening elements or layers may be present. In addition, it will also be understood that when an element or layer is referred to as being “between” two elements or layers, it may be the only element or layer between the two elements or layers, or one or more intervening elements or layers may also be present.

Further, as used herein, when a layer, film, region, plate, or the like is disposed “on” or “on a top” of another layer, film, region, plate, or the like, the former may directly contact the latter or still another layer, film, region, plate, or the like may be disposed between the former and the latter. As used herein, when a layer, film, region, plate, or the like is directly disposed “on” or “on a top” of another layer, film, region, plate, or the like, the former directly contacts the latter and still another layer, film, region, plate, or the like is not disposed between the former and the latter. Further, as used herein, when a layer, film, region, plate, or the like is disposed “below” or “under” another layer, film, region, plate, or the like, the former may directly contact the latter or still another layer, film, region, plate, or the like may be disposed between the former and the latter. As used herein, when a layer, film, region, plate, or the like is directly disposed “below” or “under” another layer, film, region, plate, or the like, the former directly contacts the latter and still another layer, film, region, plate, or the like is not disposed between the former and the latter.

In descriptions of temporal relationships, for example, temporal precedent relationships between two events such as “after”, “subsequent to”, “before”, etc., another event may occur therebetween unless “directly after”, “directly subsequent” or “directly before” is not indicated.

When a certain aspect may be implemented differently, a function or an operation specified in a specific block may occur in a different order from an order specified in a flowchart. For example, two blocks in succession may be actually performed substantially concurrently, or the two blocks may be performed in a reverse order depending on a function or operation involved.

It will be understood that, although the terms “first”, “second”, “third”, and so on may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

The features of the various aspects of the present disclosure may be partially or entirely combined with each other, and may be technically associated with each other or operate with each other. The aspects may be implemented independently of each other and may be implemented together in an association relationship.

In interpreting a numerical value, the value is interpreted as including an error range unless there is no separate explicit description thereof.

Unless otherwise defined, all terms including technical and scientific terms used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Spatially relative terms, such as “beneath,” “below,” “lower,” “under,” “above,” “upper,” and the like, may be used herein for ease of explanation to describe one element or feature's relationship to another element or feature as illustrated in the figures. It will be understood that the spatially relative terms are intended to encompass different orientations of the device in use or in operation, in addition to the orientation depicted in the figures. For example, when the device in the drawings may be turned over, elements described as “below” or “beneath” or “under” other elements or features would then be oriented “above” the other elements or features. Thus, the example terms “below” and “under” may encompass both an orientation of above and below. The device may be otherwise oriented for example, rotated 90 degrees or at other orientations, and the spatially relative descriptors used herein should be interpreted accordingly.

As used herein, “aspects,” “examples,” “aspects, and the like should not be construed such that any aspect or design as described is superior to or advantageous over other aspects or designs.

Further, the term ‘or’ means ‘inclusive or’ rather than ‘exclusive or’. That is, unless otherwise stated or clear from the context, the expression that ‘x uses a or b’ means any one of natural inclusive permutations.

The terms used in the description below have been selected as being general and universal in the related technical field. However, there may be other terms than the terms depending on the development and/or change of technology, convention, preference of technicians, etc. Therefore, the terms used in the description below should not be understood as limiting technical ideas, but should be understood as examples of the terms for illustrating aspects.

Further, in a specific case, a term may be arbitrarily selected by the applicant, and in this case, the detailed meaning thereof will be described in a corresponding description section. Therefore, the terms used in the description below should be understood based on not simply the name of the terms, but the meaning of the terms and the contents throughout the Detailed Descriptions.

As used herein, the term “display apparatus” may include, in a narrow sense, a display apparatus including a liquid crystal module (LCM), an organic light-emitting diode (OLED) module, or a quantum dot (QD) module including a display panel and a driver for driving the display panel. Moreover, the display apparatus may include, in a broad sense, a laptop computer, a television, a computer monitor, an automotive device or an equipment display for a vehicle, a set electronic device, a set device or a set device including a complete product or a final product including the LCM, the OLED module, or the QD module.

Therefore, the display apparatus in accordance with the present disclosure may include, in the narrow sense, a display apparatus itself including, for example, the LCM, the OLED module, QD module, etc., and may include, in a broad sense, the set device as an application product or an end-user device including a complete product or a final product including the LCM, the OLED module, or the QD module.

Moreover, in some cases, the LCM, OLED module, or QD module composed of the display panel and the driver may be expressed as “display apparatus” in a narrow sense. The electronic device as a complete product including the LCM, OLED module or QD module may be expressed as “set” device” in a broad sense. For example, the display apparatus in the narrow sense may include a display panel such as a liquid crystal panel, an organic light-emitting display panel, or a quantum dot display panel, and a source PCB as a controller for driving the display panel. The set device in the broad sense may include a display panel such as a liquid crystal panel, an organic light-emitting display panel, or a quantum dot display panel, a source PCB as a controller for driving the display panel, and a set PCB as a set controller that is electrically connected to the source PCB and controls the set device.

As used herein, the display panel may be of any type of the display panels such as a liquid crystal display panel, an organic light emitting diode (OLED) display panel, a quantum dot (QD) display panel, and an electroluminescent display panel, etc. The display panel used in the disclosure may be not limited to a specific display panel including a flexible substrate for the OLED display panel and an underlying back plate support structure and having a bendable bezel. Moreover, the display panel used in the display apparatus according to an aspect of the present disclosure is not limited to a shape or a size of the display panel.

More specifically, when the display panel is embodied as the organic light emitting diode (OLED) display panel, the display panel may include a plurality of gate lines and data lines, and pixels respectively formed in areas where the gate lines and the data lines intersect with each other. Moreover, the display panel may be configured to include an array including a thin-film transistor as an element for selectively applying a voltage to each pixel, an organic light-emitting element layer on the array, and an encapsulation substrate or an encapsulation layer disposed on the array to cover the organic light-emitting element layer. The encapsulation layer protects the thin-film transistor and the organic light-emitting element layer from external impact, and may prevent moisture or oxygen from penetrating into the organic light-emitting element layer. Moreover, the light emitting layer formed on the array may include an inorganic light emitting layer, for example, a nano-sized material layer, or a quantum dot.

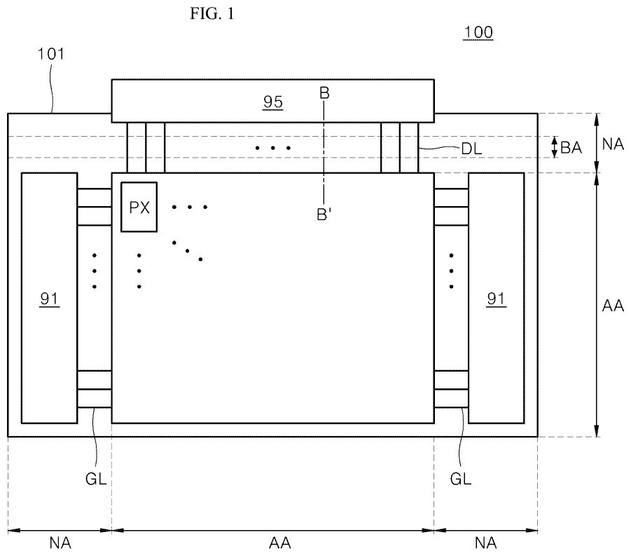

FIG. 1 is a plan view showing a display apparatus according to an aspect of the present disclosure.

A display apparatus 1 according to an aspect of the present disclosure may include a display panel 100. The display panel 100 may include a display area AA provided on a substrate 101 and a non-display area NA disposed around the display area AA.

The substrate 101 may be made of a plastic material that has flexibility to allow bending. For example, the substrate 101 may be made of polyimide (PI), polyethylene terephthalate (PET), polyethylene naphthalate (PEN), polycarbonate (PC), polyethersulfone (PES), polyarylate (PAR), polysulfone (PSF), or cyclic-olefin copolymer (COC). However, aspects of the present disclosure are not limited thereto. For example, glass is not excluded as a material for the substrate 101. In another aspect of the present disclosure, the substrate 101 may be made of a semiconductor material such as a silicon wafer.

The display area AA may be an area where a plurality of sub-pixels PX are arranged and an image is displayed. Each of the plurality of sub-pixels PX may be a unit that individually emits light. A light-emitting element and a driving circuit may be disposed in each of the plurality of sub-pixels PX. For example, a display element for displaying an image and a circuit unit for driving the display element may be disposed in each of the plurality of sub-pixels PX. For example, when the display apparatus is an organic light-emitting display apparatus, the display element may include an organic light-emitting element. When the display apparatus is a liquid crystal display apparatus, the display element may include a liquid crystal light-emitting element. The plurality of sub-pixels PX may include a red sub-pixel PX, a green sub-pixel PX, a blue sub-pixel PX, and/or a white sub-pixel PX, etc. However, aspects of the present disclosure are not limited thereto.

The non-display area NA may be an area where the image is not displayed. The non-display area NA may be an area where various wirings and a driver IC for driving the plurality of sub-pixels PX arranged in the display area AA are disposed. For example, at least one of a data driver 95 and a gate driver 91 may be disposed in the non-display area NA. However, aspects of the present disclosure are not limited thereto.

The non-display area NA may be an area surrounding the display area AA. For example, the non-display area NA may be defined around the display area AA. For example, the non-display area NA may be an area extending from the display area AA, or may be an area where the plurality of sub-pixels PX are not disposed. However, aspects of the present disclosure are not limited thereto.

The non-display area NA in which the image is not displayed may be a bezel area or may further include a bent area BA where the substrate 101 is bent. However, aspects of the present disclosure are not limited thereto.

A plurality of data lines DL and a plurality of gate lines GL may be arranged and disposed in the display area AA. For example, the plurality of data lines DL may extend in a row or column direction, while the plurality of gate lines GL may extend in the column or row direction. The sub-pixel PX may be disposed at an intersection of the data line DL and the gate line GL.

The sub-pixel PX of the display area AA may include a thin-film transistor or an oxide semiconductor transistor (e.g., MOSFET) including a semiconductor layer. For example, the thin-film transistor or the oxide semiconductor transistor may include an oxide semiconductor material. However, aspects of the present disclosure are not limited thereto. For example, the present disclosure is not limited to the term.

According to an aspect of the present disclosure, the gate driver 91 including a gate driving circuit may be disposed in the non-display area NA. The gate driving circuit of the gate driver 91 may sequentially drive pixel rows of the display area AA by sequentially supplying a scan signal to the plurality of gate lines GL. For example, the pixel row may be a row of pixels connected to one gate line. The gate driving circuit may be referred to as a scan driving circuit. The present disclosure is not limited to the term.

According to an aspect of the present disclosure, the gate drivers 91 may be arranged symmetrically in a left-right direction on both opposing sides of the display area AA, respectively. However, aspects of the present disclosure are not limited thereto. For example, the gate driver 91 may include a scan driver and/or an EM (emission) driver.

The gate driving circuit may be composed of a thin-film transistor with a polycrystalline semiconductor layer, or may be composed of a thin-film transistor having an oxide semiconductor layer, or may be composed of a pair of a thin-film transistor having a polycrystalline semiconductor layer and a thin-film transistor having an oxide semiconductor layer. When the same semiconductor material is used for the thin-film transistors respectively disposed in the non-display area NA and the display area AA, the thin-film transistors respectively disposed in the non-display area NA and the display area AA may be formed simultaneously in the same process. However, aspects of the present disclosure are not limited thereto.

The gate driving circuit may include a shift register and a level shifter.

The gate driving circuit may be implemented in a GIP (Gate In Panel) form and thus disposed directly on the substrate 101 as in the display apparatus according to an aspect of the present disclosure.

The gate driver 91 including the gate driving circuit may sequentially supply the scan signal of an on voltage or an off voltage to the plurality of gate lines GL.

The gate driver 91 according to an aspect of the present disclosure may include a thin-film transistor using a polycrystalline semiconductor material as a semiconductor layer material, and may be formed directly on the substrate 101. Alternatively, the gate driver 91 according to an aspect of the present disclosure may include a CMOS (complementary metal-oxide-semiconductor) composed of a thin-film transistor using an oxide semiconductor material as a semiconductor layer material and a thin-film transistor using a polycrystalline semiconductor material as a semiconductor layer material.

For example, the oxide semiconductor material may include at least one of an IGZO (InGaZnO)-based oxide semiconductor material, an IZO (InZnO)-based oxide semiconductor material, an IGZTO (InGaZnSnO)-based oxide semiconductor material, an ITZO (InSnZnO)-based oxide semiconductor material, a FIZO (FeInZnO)-based oxide semiconductor material, a ZnO-based oxide semiconductor material, a SIZO (SiInZnO)-based oxide semiconductor material, and a ZnON (Zn-Oxynitride)-based oxide semiconductor material. However, aspects of the present disclosure are not limited thereto.

When the gate driver 91 according to an aspect of the present disclosure includes the thin-film transistor with an oxide semiconductor layer and a thin-film transistor with a polycrystalline semiconductor layer, high electron mobility in a channel may result in high-resolution and low-power implementation.

The display apparatus 1 according to an aspect of the present disclosure may further include the data driver 95 including a data driving circuit. When a specific gate line is opened by the gate driver 91 including the gate driving circuit, the data driving circuit may convert image data into an analog data voltage and supply the analog data voltage to the plurality of data lines. For example, the gate drivers 91 may be arranged symmetrically in the left-right direction on both opposing sides of the display area AA, respectively. However, aspects of the present disclosure are not limited thereto.

The plurality of gate lines GL disposed on the substrate 101 may include a plurality of scan lines and a plurality of emission control lines. The plurality of scan lines and the plurality of light-emission control lines may transmit different types of gate signals (scan signals and light-emission control signals) to gate nodes of different types of transistors (scan transistors and light-emission control transistors).

The gate driver 91 including the gate driving circuit may include the scan driving circuit which outputs scan signals to the plurality of scan lines as one type of the gate line GL, and the light-emission driving circuit that outputs the light-emission control signals to the plurality of light-emission control lines as the other type of the gate line.

The display panel 100 according to an aspect of the present disclosure may further include the bent area BA where the substrate 101 is bent. However, aspects of the present disclosure are not limited thereto. The bent area BA may be an area where the substrate 101 is bent. The substrate 101 may be maintained in a flat state in an area except for the bent area BA. The data line DL may pass through the bent area BA, and may include various data lines DL connected to a data pad.

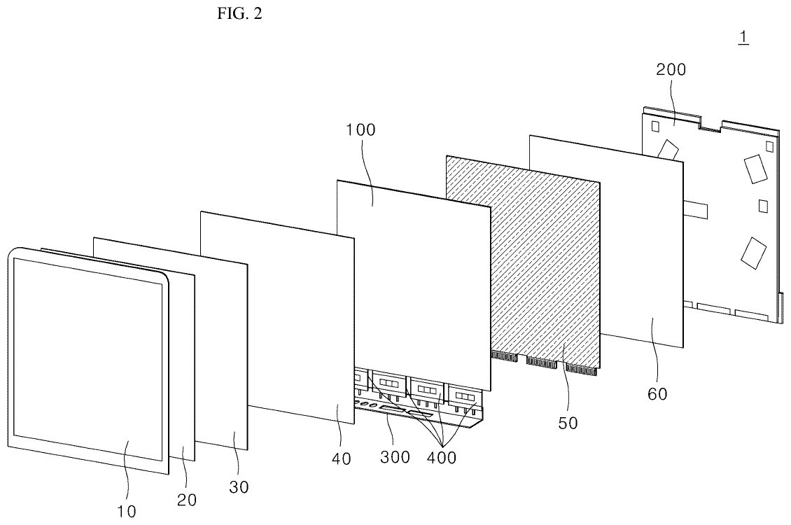

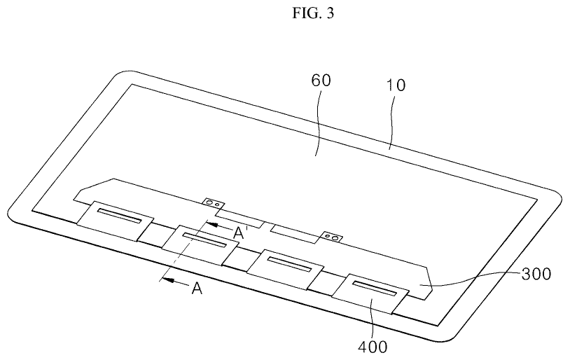

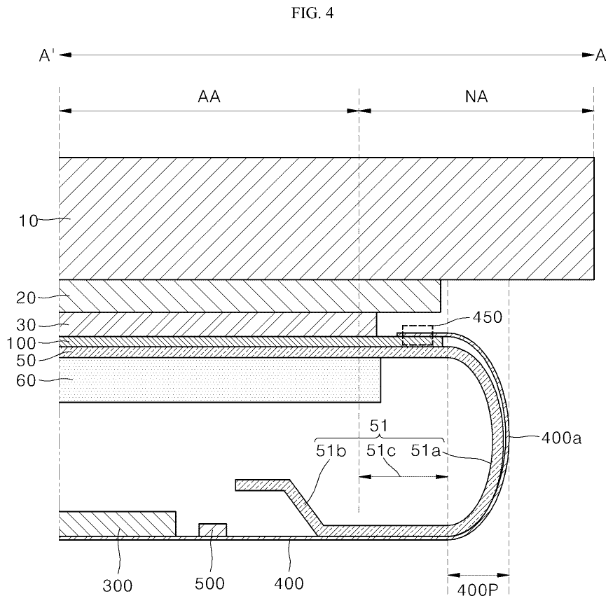

FIG. 2 is an exploded perspective view showing the display apparatus according to an aspect of the present disclosure. FIG. 3 is a rear view of the display apparatus in a state in which some components of FIG. 2 are omitted. FIG. 4 is a cross-sectional view of the display apparatus according to one aspect of the present disclosure. FIG. 4 is a cross-sectional view taken along line A-A′ in FIG. 3.

In one example, the display apparatus according to an aspect of the present disclosure may be mounted on a vehicle to provide a driver and a passenger of the vehicle with an image or a video necessary for driving of the vehicle. However, the present disclosure is not limited thereto and the display apparatus according to an aspect of the present disclosure may be used while being carried by a user rather than being mounted on the vehicle. Hereinafter, an example in which the display apparatus is mounted on the vehicle will be described. However, aspects of the present disclosure are not limited thereto.

Referring to FIGS. 2 to 4, the display apparatus according to an aspect of the present disclosure may include the display panel 100, a plate 60 disposed on a rear surface of the display panel 100, and a printed circuit board 300 and a circuit film 400 (chip on film, COF) electrically connected to the display panel 100.

A moving image or a still image may be played or displayed on the display panel 100. For example, the moving image or the sill image that is played or displayed thereon may include navigation information necessary for driving of the vehicle, a moving image captured by a camera mounted on the vehicle, or various other contents necessary for the driver or passengers. However, aspects of the present disclosure are not limited thereto.

A guide panel 200 may be disposed in rear surface of the display panel 100. The guide panel 200 may be the rearmost component of the display apparatus. Various parts of the display apparatus including the display panel 100 may be mounted on the guide panel 200. For example, the guide panel 200 may be mounted in a cockpit area of the vehicle. For this purpose, the guide panel 200 may be provided with a necessary coupling structure such as a screw hole.

The printed circuit board 300 may be electrically connected to the display panel 100. The printed circuit board 300 may include a device for communicating with external devices such as cameras and a main control module of the vehicle, and a device that drives the display panel 100 so that the display panel 100 reproduces or displays the still image or the moving image. An internal circuit may be provided in the printed circuit board 300. Various other active and passive elements may be included in the printed circuit board 300.

One side of the circuit film 400 may be electrically connected to the display panel 100, and the other side may be electrically connected to the printed circuit board 300. A portion of the circuit film 400 may be bent to surround the guide panel 200. FIG. 2 shows an example in which the circuit film 400 is not bent.

The circuit film 400 may be thin and made of a flexible material to allow bending. The circuit film 400 may electrically connect the display panel 100 and the printed circuit board 300 to each other. For example, the circuit film 400 may be equipped with various active and passive elements, and may be equipped with a driving circuit that drives the display panel 100.

The driving circuit that drives the display panel 100 may be configured to be distributed in the printed circuit board 300 and the circuit film 400. Referring to FIG. 4, the circuit film 400 may be provided with a driver chip 500 that constitutes at least a portion of the driving circuit of the display panel 100. A plurality of circuit films 400 may be provided. Referring to FIG. 3, at least two circuit films 400 may be arranged to be spaced apart from each other.

The display apparatus according to an aspect of the present disclosure may further include a cover member 10, a first fixing member 20, a functional film 30, and a second fixing member 40 disposed on a front surface of the display panel 100. The second fixing member 40, the functional film 30, the first fixing member 20, and the cover member 10 may be sequentially stacked on the display panel 100. The display apparatus according to an aspect of the present disclosure may further include a support member 50 and a plate 60 disposed on the rear surface of the display panel 100 and acting as a support structure to support display panel 100. Each of the components included in the display apparatus may be formed in a thin shape to produce a slim display apparatus.

The cover member 10 may be disposed in front surface of the display panel 100 to protect the display panel 100. The cover member 10 may be made of a transparent material so that light emitted from the display panel 100 may travel through the cover member 10.

In an aspect, the functional film 30 may include a light angle adjustment structure to adjust a visible range of the image displayed on the display panel 100. The light angle adjustment structure may be provided in a trapezoidal pattern with an angle adjusted in a cross-sectional view to be adapted to a target visible range and may be disposed in the functional film 30. The trapezoid-shaped pattern may be made of a light-blocking material. However, aspects of the present disclosure are not limited thereto. For example, the functional film 30 may include a polarizer that controls display characteristics (e. g., external light reflection, color accuracy, luminance, etc.). In some cases, the functional film 30 may be omitted. In another example, the functional film 30 may be patterned on the uppermost surface of the display panel 100 or an inner surface of the cover member 20. However, aspects of the present disclosure are not limited thereto. The first fixing member 20 may be disposed between the cover member 10 and the functional film 30. One surface of the first fixing member 20 may be adhered to the cover member 10 and the other surface thereof may be adhered to the functional film 30, so that the functional film 30 may be adhered to the cover member 10 via the first fixing member 20.

The second fixing member 40 may be disposed between the functional film 30 and the display panel 100. One surface of the second fixing member 40 may be adhered to the functional film 30 and the other surface thereof may be adhered to the display panel 100, so that the functional film 30 may be adhered to the display panel 100 via the second fixing member 40.

Each of the first fixing member 20 and the second fixing member 40 may be made of a transparent material having good adhesion, for example, OCA (Optically Clear Adhesive) or OCR (Optically Cleared Resin). However, aspects of the present disclosure are not limited thereto.

The support member 50 may be disposed on the rear surface of the display panel 100. The support member 50 may be attached to the rear surface of the display panel 100 to prevent the display panel 100 from being bent and damaged. For example, the support member 50 may reinforce rigidity of the display panel 100 supported on the support member 50.

The support member 50 may be provided, for example, in a form of a film, and attached to the display panel 100. However, aspects of the present disclosure are not limited thereto.

The support member 50 may be attached to a surface (second surface) opposite to a surface (first surface) on which the light-emitting element is disposed, among both opposing surfaces of a substrate of the display panel 100. The support member 50 may be embodied as a thin film made of polyethylene naphthalate (PEN), polyethylene terephthalate (PET), polyethylene ether phthalate, polycarbonate, polyarylate, polyether imide, polyether sulfonate, polyimide, polyacrylate, or a combination thereof. Alternatively, the support member 50 may be embodied as a thin glass, a dielectric-shielded metal foil, a multilayer polymer film, or a polymer film made of a polymer material in combination with nanoparticles or micro particles, etc. The support member 50 for supporting the display panel may be thicker than the display panel 100. However, aspects of the present disclosure are not limited thereto.

When the support member 50 is included in the display apparatus, the rear surface of the display panel 100 may be attached to the support member 50, and then a fastening process of the support member 50 to the plate 60 may be performed. However, aspects of the present disclosure are not limited thereto.

For example, the plate 60 may be disposed in rear surface of the support member 50 and in front surface of the guide panel 200. The plate 60 may contact a rear surface of the support member 50, and may serve as a heat sink to cool the display panel 100 by dissipating heat generated from the display panel 100 to the outside.

The plate 60 may be made of a material which is easily subjected to sheet metal processing, has a high heat transfer rate, and excellent resistance, for example, aluminum. Aspects of the present disclosure are not limited thereto.

FIG. 3 is a rear view of the display apparatus in FIG. 2 in a state in which components such as the guide panel are omitted for convenience of illustration. For example, FIG. 3 is a plan view showing a state in which the circuit film in FIG. 2 is in a bent state. FIG. 4 is a cross-sectional view taken along line A-A′ in FIG. 3. Referring to FIGS. 3 to 4, the circuit film 400 may be bent. For example, one side of the circuit film 400 may be connected to the display panel 100, and the other side thereof may be connected to the printed circuit board 300. The circuit film 400 may be bent such that the other side of the circuit film 400 and the printed circuit board 300 may be disposed on the rear surface of the display panel 100. For example, at least one circuit film 400 may be thin and be made of a flexible material to allow bending thereof. At least a portion of the at least one circuit film 400 may be bent. The printed circuit board 300 may be electrically connected to one side of the display panel 100. Referring to FIG. 4, the display apparatus according to an aspect of the present disclosure further includes a driver chip 500 disposed on one side of the display panel 100, and the driver chip 500 may be disposed on the circuit film 400.

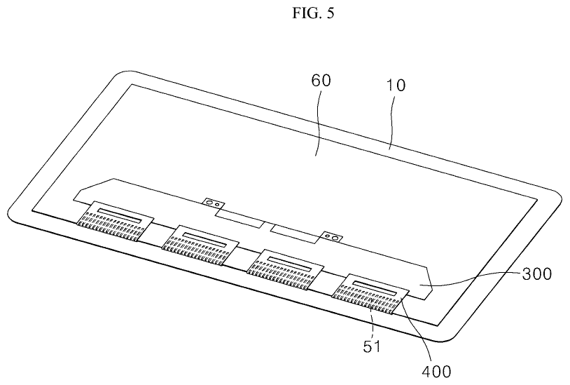

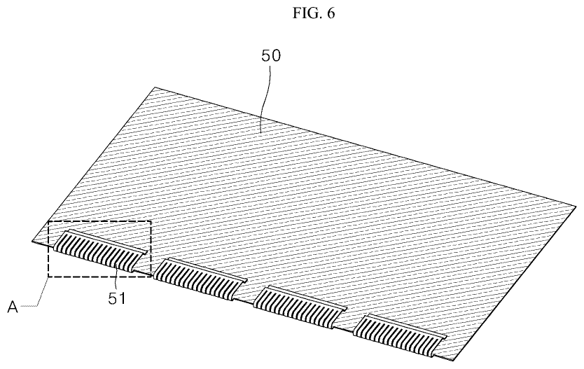

FIG. 5 is a plan view of a state in which the support member is bent in the display apparatus of FIG. 4. For example, FIG. 5 is a plan view in which an extension 51 of the support member 50 in FIG. 3 is visible. FIG. 6 is a plan view of the support member according to an aspect of the present disclosure.

Referring to FIGS. 4 and 5, according to an aspect, the support member 50 may include at least one extension 51 protruding from a side surface of the display panel 100. For example, in the non-display area NA of the display apparatus, the extension 51 of the support member 50 may overlap the circuit film 400 on the rear surface of the circuit film 400. For example, the extension 51 of the support member 50 may be bent from one side of the support member 50 toward the rear surface of the display panel 100. For example, the circuit film 400 disposed on the extension 51 may be bent toward the rear surface of the display panel 100. For example, the circuit film 400 disposed on the extension 51 may be bent in the same direction in a direction in which the extension 51 is bent. Aspects of the present disclosure are not limited thereto.

For example, the at least one extension 51 of the support member 50 may be bent from one side of the support member 50 toward the rear surface of the display panel 100. For example, the driver chip 500 may be disposed on the rear surface of the display panel 100. For example, the driver chip 500 may be disposed on a rear surface of the circuit film 400. Aspects of the present disclosure are not limited thereto.

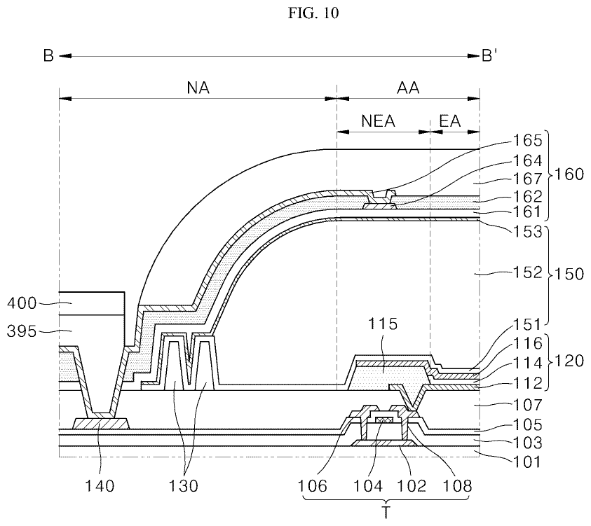

Referring to FIG. 4, to implement a narrow bezel, a bezel size of the non-display area NA may be reduced as a size of a protruding area 400P of the bent circuit film 400 decreases. For example, the circuit film 400 is bent by pulling the circuit film as excessively as possible to minimize the size of the protruding area 400P of the circuit film 400, the circuit film 400 and the display panel 100 are not reliably connected to each other at a connection area 450, such that electrical signal defect may occur due to damage to a pad 140 (see FIG. 10) of the display panel 100. For example, when there is a layer supporting the bent portion 400a of the circuit film 400, the size of the protruding area 400P of the circuit film 400 may be minimized. For example, the support member 50 may include the at least one extension 51 protruding from the side surface of the display panel 100. For example, the support member 50 may at least partially overlap the circuit film 400 in the protruding area 400P of the circuit film 400.

For example, the extension 51 of the support member 50 may include a bent portion 51a supporting the rear surface of the circuit film 400. For example, the extension 51 of the support member 50 may include a non-contact portion 51b that does not contact the circuit film 400. For example, a sharp tip end of the extension 51 of the support member 50 may be prevented from contacting the circuit film 400, such that interference or damage to the circuit film 400 which is thinner than the support member 50 and is softer than the support member 50 may prevented. Aspects of the present disclosure are not limited thereto.

For example, the at least one extension 51 of the support member 50 may include a contact portion 51c that contacts the circuit film 400 and is disposed between the bent portion 51a and the non-contact portion 51b that does not contact the circuit film 400. Aspects of the present disclosure are not limited thereto.

FIG. 6 is a plan view of the support member according to an aspect of the present disclosure.

Referring to FIGS. 2 to 6, for example, the at least one extension 51 of the support member 50 may include a plurality of extensions which may be spaced apart from each other. The number of the extensions 51 of the support member 50 according to an aspect of the present disclosure may be equal to the number of the circuit films 400. For example, the at least one extension 51 of the support member 50 may overlap with the at least one circuit film 400. For example, at least a portion of the support member 50 may be in contact with the at least one circuit film 400. For example, the at least one extension 51 of the support member 50 may be in at least partial contact with the at least one circuit film 400. For example, the extension 51 of the support member 50 may be disposed on the rear surface of the circuit film 400 and may have one-to-one correspondence therewith. Aspects of the present disclosure are not limited thereto.

For example, the extension 51 of the support member 50 may not be divided into portions spaced apart from each other but may have an integrated structure. Thus, an area in which the extension 51 does not overlap with the circuit film 400 may be present.

For example, the number of the at least one extension 51 of the support member 50 may be different from the number of the at least one circuit film 400. The number of the circuit films 400 and/or the number of the extensions 51 of the support member 50 in the drawing according to an aspect of the present disclosure are merely examples. However, aspects of the present disclosure are not limited thereto.

For example, a material of the support member 50 and a material of the circuit film 400 may be different from each other. The material of the support member 50 may include, for example, polyethylene terephthalate (PET). The material of the circuit film 400 may include, for example, polyimide (PI). However, aspects of the present disclosure are not limited thereto, and the material of the support member 50 and the material of the circuit film 400 may be the same as each other.

For example, a thickness of the support member 50 and a thickness of the circuit film 400 may be different from each other. For example, since the support member 50 supports the display panel 100, the support member 50 may be thicker than the circuit film 400 connecting the printed circuit board 300 and the display panel 100 to each other.

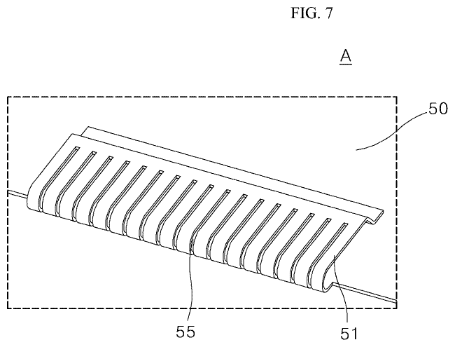

FIG. 7 is a diagram showing area A of FIG. 6 according to an aspect of the present disclosure.

Referring to FIG. 7, for example, the support member 50 may include at least one opening 55. For example, the at least one extension 51 of the support member 50 may include the at least one opening 55. According to the present disclosure, the at least one opening 55 of the at least one extension 51 of the support member 50 may include a straight shape (or pattern). However, aspects of the present disclosure are not limited thereto. For example, since the support member 50 may be made of plastic, the at least one opening 55 of the at least one extension 51 of the support member 50 may include a mesh pattern to prevent cracks and operation failures due to contraction or expansion in different environments such as high temperature, low temperature, and high humidity. For example, the support member 50 may include the extension 51 to support and/or guide the circuit film 400 while the extension 51 may include the opening 55 to ensure quality in the reliable environment. For example, at least one of the shapes of the opening 55 may be bent in the same direction as the direction in which the extension is bent. For example, the straight shape (mesh pattern) of the opening 55 may be bent in the direction in which the at least one extension 51 of the support member 50 is bent. Aspects of the present disclosure are not limited thereto.

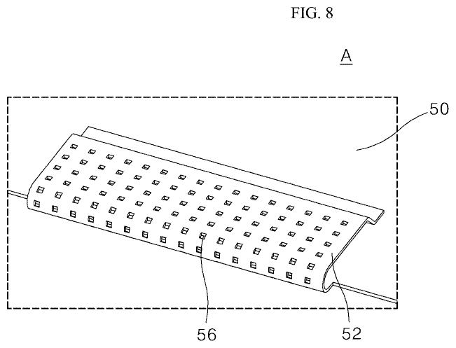

FIG. 8 is a diagram showing area A of FIG. 6 according to another aspect of the present disclosure. Referring to FIG. 8, according to another aspect of the present disclosure, at least one opening 56 of at least one extension 52 of the support member 50 may include a square hole shape (pattern). However, aspects of the present disclosure are not limited thereto. For example, at least one of the shapes of the opening 56 may be bent in the direction in which the extension is bent. For example, the square hole shape of the opening 56 may be bent in the direction in which the at least one extension 52 of the support member 50 is bent. Aspects of the present disclosure are not limited thereto.

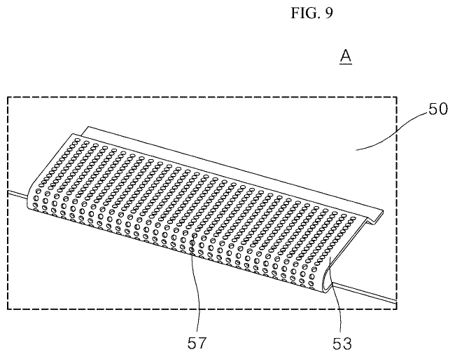

FIG. 9 is a diagram showing area A of FIG. 6 according to still another aspect of the present disclosure. Referring to FIG. 9, according to still another aspect of the present disclosure, at least one opening 57 of at least one extension 53 of the support member 50 may include a circular shape, or a fine circular pattern. Aspects of the present disclosure are not limited thereto. For example, at least one of the shapes of the opening 57 may be bent in the direction in which the extension is bent. For example, the fine circular hole shape of the opening 57 may be bent in the direction in which the at least one extension 53 of the support member 50 is bent. Aspects of the present disclosure are not limited thereto.

FIG. 10 is a cross-sectional view of the display panel taken along line B-B′ in FIG. 1 according to an aspect of the present disclosure.

Referring to FIG. 10, the display panel 100 of the display apparatus 1 according to an aspect of the present disclosure includes a substrate 101, a thin-film transistor T, a planarization layer 107, a light-emitting element 120, the bank 115, a pad 140, a dam 130, an encapsulation portion 150, and a touch unit 160.

The thin-film transistor T is disposed on the substrate 101. The thin-film transistor T transmits data voltage to a plurality of sub-pixels.

The substrate 101 supports various components of the display panel 100. The substrate 101 may be made of a transparent insulating material, such as glass or plastic. When the substrate 101 is made of plastic, the substrate may be referred to as a plastic film or plastic substrate. For example, the substrate 101 may be in a form of a film including one of polyimide-based polymers, polyester-based polymers, silicone-based polymers, acrylic polymers, polyolefin-based polymers, and copolymers thereof. However, aspects of the present disclosure are not limited thereto. For example, since polyimide is material that may be applied to a high temperature process and may be coated may be used as a material of a plastic substrate. The substrate (array substrate) may include elements and functional layers formed on the substrate 101, such as a switching TFT, a driving TFT connected to the switching TFT, the light-emitting element 120 connected to the driving TFT, and the encapsulation portion 150. However, aspects of the present disclosure are not limited thereto.

A buffer layer may be disposed on the substrate 101. The buffer layer may protect the thin-film transistor (TFT) from impurities such as alkali ions leaking from the substrate 101 or underlying layers. The buffer layer may be made of silicon oxide (SiOx), silicon nitride (SiNx), or a multilayer thereof. However, aspects of the present disclosure are not limited thereto.

The thin-film transistor T may be disposed on the substrate 101 or the buffer layer. The thin-film transistor T may include an active layer 102, a gate insulating layer 103, a gate electrode 104, an interlayer insulating layer 105, a source electrode 106, and a drain electrode 108. The active layer 102 is disposed on the substrate 101 or the buffer layer. The active layer 102 may be made of polysilicon (p-Si), wherein a predetermined area thereof may be doped with impurities. Furthermore, the active layer 102 may be made of amorphous silicon (a-Si), or may be made of various organic semiconductor materials such as pentacene. The active layer 102 may be made of oxide. However, aspects of the present disclosure are not limited thereto in terms of the material constituting the active layer 102. The active layer 102 may be a semiconductor layer. However, the present disclosure is not limited to the terms as used herein.

Depending on a structure of the thin-film transistor T, the gate electrode 104 may be disposed on top of or under the active layer 102. The gate electrode 104 may be made of each of various conductive materials, such as magnesium (Mg), aluminum (Al), nickel (Ni), chromium (Cr), molybdenum (Mo), tungsten (W), gold (Au), or alloys thereof, etc. However, aspects of the present disclosure are not limited thereto.

The gate insulating layer 103 may be disposed between the active layer 102 and the gate electrode 104. The gate insulating layer 103 may be a layer for electrically insulating the gate electrode 104 and the active layer 102 from each other, and may be made of an insulating material. For example, the gate insulating layer 103 may be formed as a single or double layer made of silicon oxide (SiOx) or silicon nitride (SiNx). However, aspects of the present disclosure are not limited thereto. The gate insulating layer 103 may be a first insulating layer. However, aspects of the present disclosure are not limited thereto.

The source electrode 106 and the drain electrode 108 that are electrically connected to the active layer 102 and are spaced apart from each other may be disposed on the interlayer insulating layer 105. Each of the source electrode 106 and the drain electrode 108 may be made of a conductive material, for example, copper (Cu), aluminum (Al), molybdenum (Mo), titanium (Ti), or an alloy thereof. However, aspects of the present disclosure are not limited thereto. The interlayer insulating layer 105 may be a second insulating layer. However, aspects of the present disclosure are not limited thereto.

According to the structure of the thin-film transistor T, to electrically insulate the gate electrode 104 and each of the source electrode 106 and the drain electrode 108, an interlayer insulating layer 105 may be further disposed between the gate electrode 104 and each of the source electrode 106 and the drain electrode 108. However, aspects of the present disclosure are not limited thereto.

The planarization layer 107 may be disposed on the thin-film transistor T. The planarization layer 107 protects the thin-film transistor T and planarizes a portion on top of the thin-film transistor T. The planarization layer 107 may be disposed in a display area AA. The planarization layer 107 may not be disposed in an entirety or a portion of a non-display area NA. For example, the planarization layer 107 may be formed in various shapes. The planarization layer 107 may be composed of an organic insulating film made of, for example, BCB (Benzocyclobutene) or acryl resin, or an inorganic insulating film such as a silicon nitride film (SiNx) or a silicon oxide film (SiOx). The planarization layer 107 may be formed as a single layer or double or multiple layers. That is, various modifications may be applied to the planarization layer 107. However, aspects of the present disclosure are not limited thereto. The planarization layer 107 may be formed with a contact hole CH for electrically connecting the thin-film transistor T and the light-emitting element 120 to each other. The planarization layer 107 may be a third insulating layer or a protective layer. However, aspects of the present disclosure are not limited thereto.

The light-emitting element 120 is disposed on the planarization layer 107. The light-emitting element 120 may be a self-light-emitting element that emits light by itself, and may operate upon receiving voltage from a transistor, etc. The light-emitting element 120 may include a first electrode 112, a light-emitting layer 114, and a second electrode 116.

For example, the light-emitting element 120 may include the first electrode 112 formed on the planarization layer 107, the light-emitting layer 114 disposed on the first electrode 112, and the second electrode 116 disposed on the light-emitting layer 114. For example, the light-emitting element 120 may be a self-light-emitting element that emits light by itself, and may operate upon receiving voltage from the thin-film transistor T, etc.

The first electrode 112 may be electrically connected to the drain electrode 108 of the driving thin-film transistor T via the contact hole CH. The first electrode 112 may be made of a conductive material capable of supplying holes to the light-emitting layer 114. When the display panel 100 is of a top emission type, the first electrode 112 may be made of an opaque conductive material with high reflectivity. For example, the first electrode 112 may be made of silver (Ag), aluminum (Al), gold (Au), molybdenum (Mo), tungsten (W), chromium (Cr), or an alloy thereof. However, aspects of the present disclosure are not limited thereto.

The bank 115 is disposed on the first electrode 112 and the planarization layer 107. The bank 115 may act as an insulating layer to distinguish adjacent sub-pixels from each other. The bank 115 may be disposed to open a portion of the first electrode 112. The bank 115 may be made of an organic insulating material and may be disposed to cover an edge of the first electrode 112. However, aspects of the present disclosure are not limited thereto.

The bank 115 is formed in a remaining area excluding the light-emitting area EA.

Accordingly, the bank 115 may have a bank hole defined therein that exposes a portion of the first electrode 112 corresponding to the light-emitting area. The bank 115 may be made of an inorganic insulating material such as silicon nitride (SiNx) or silicon oxide (SiOx), or an organic insulating material such as BCB, acrylic resin, or imide resin. However, aspects of the present disclosure are not limited thereto.

The light-emitting layer 114 is disposed on the portion of the first electrode 112 not covered with the bank 115 to be exposed. The light-emitting layer 114 may include a light-emitting layer, an electron injection layer, an electron transport layer, an electron blocking layer, a hole transport layer, a hole blocking layer, and a hole injection layer. However, aspects of the present disclosure are not limited thereto. The light-emitting layer may be composed of a single light-emitting layer structure that emits light of a single color, or may be composed of a plurality of light-emitting layers such that white light is emitted as a mixture of light beams respectively emitted from the plurality of light-emitting layers. A charge generation layer may be further disposed between adjacent ones of the plurality of light-emitting layers.

Referring to FIG. 10, it is shown that the light-emitting layers 114 respectively disposed in the sub-pixels are disconnected from each other. However, aspects of the present disclosure are not limited thereto. For example, the light-emitting layer 114 may be formed as a single layer across the plurality of sub-pixels or across some of the plurality of sub-pixels.

The second electrode 116 may be disposed on the light-emitting layer 114. The second electrode 116 may be made of a conductive material that may supply electrons to the light-emitting layer 114. For example, the second electrode 116 may be made of a transparent conductive oxide such as indium tin zinc oxide (ITZO), zinc oxide (ZnO), and tin oxide (TO), or ytterbium (Yb) alloy. However, aspects of the present disclosure are not limited thereto. The second electrode 116 may be formed as a very thin-film made of a metal material. However, aspects of the present disclosure are not limited thereto. When the display panel 100 is of a top emission type, the second electrode 116 may be made of a transparent conductive material such as indium tin oxide (ITO) or indium zinc oxide (IZO), or a transflective metal alloy such as MgAg alloy, such that the light generated from the light-emitting layer 114 may be emitted upwardly of the second electrode 116.

Referring to FIG. 10, it is shown that the second electrodes 116 respectively disposed in the sub-pixels are connected to each other. However, aspects of the present disclosure are not limited thereto. Like the first electrode 112, the second electrodes 116 respectively disposed in the sub-pixels are disconnected from each other. However, aspects of the present disclosure are not limited thereto.

The light-emitting layer 114 may be an organic light-emitting layer made of organic material. However, aspects of the present disclosure are not limited thereto. For example, the light-emitting layer 114 may be an inorganic light-emitting layer including an inorganic semiconductor layer, such as a quantum dot material, or an organic-inorganic mixed light-emitting layer. In some cases, the light-emitting layer 114 may have an arrangement of micro LEDs or mini LEDs.

The display area AA may include a plurality of light-emitting areas EA and a non-light-emitting area NEA between adjacent ones of the plurality of light-emitting areas EA.

An area where each of the plurality of light-emitting elements 120 is disposed may be each of the plurality of light-emitting areas EA. Each of the plurality of light-emitting areas EA may be an area that may independently emit light of one color, and may be an area corresponding to a plurality of sub-pixels, and may be an area where the bank 110 is not disposed. For example, the plurality of light-emitting areas EA may include, but is not limited to, a red light-emitting area, a green light-emitting area, and a blue light-emitting area. The plurality of light-emitting areas EA may be arranged to be spaced apart from each other. For example, the plurality of light-emitting areas EA may be arranged in a row direction and a column direction, and thus may be arranged in a matrix form. However, aspects of the present disclosure are not limited thereto.

An area in which the plurality of light-emitting element 120 is not disposed may be the non-light-emitting area NEA. The non-light-emitting area NEA may be an area disposed between adjacent ones of the plurality of light-emitting areas EA and may be an area where the bank 110 is disposed. Since the non-light-emitting area NEA is disposed to surround the plurality of light-emitting areas EA, the non-light-emitting area NEA may be in a form of a mesh. However, aspects of the present disclosure are not limited thereto.

The dam 130 may be disposed in the non-display area NA. For example, the dam 130 may be disposed on the substrate 101 and in the non-display area NA. The dam 130 may be disposed to prevent spread of a material of an organic encapsulation layer 152 of the encapsulation portion 150 disposed to cover the display area AA. For example, the dam 130 may suppress overflow of the material of the organic encapsulation layer 152 of the encapsulation portion 150. One or more dams 130 may be disposed, and the number of dams disposed is not limited to a specific number.

The pad 140 is disposed in the non-display area NA. The pad 140 may be disposed outside the dam 130. A signal may be input to a circuit area or a driver chip formed in the substrate 101 via the pad 140. For example, the pad 140 may supply a signal supplied from an external source to the circuit area, the driver chip, etc. of the substrate 101. For example, the pad 140 may supply a signal for driving the touch unit 160 to the touch unit 160 and receive a signal resulting from a user's touch input from the touch unit 160.

For example, referring to FIG. 4 and FIG. 10, the contact portion 51c of the at least one extension 51 of the support member 50 may overlap with the dam 130 and/or the pad 140 in the non-display area NA of the display panel 100.

The encapsulation portion 150 is disposed on the light-emitting element 120. The encapsulation portion 150 may act as a sealing member that protects the light-emitting material and the electrode material of the light-emitting element 120 from external moisture, oxygen, shock, etc. to prevent oxidation of the light-emitting material and the electrode material of the light-emitting element 120. The encapsulation portion 150 may be disposed to cover an entirety of the display area AA where the light-emitting element 120 is disposed. The encapsulation portion 150 may be disposed to cover a portion of the non-display area NA extending from the display area AA. The encapsulation portion 150 may include a first inorganic encapsulation layer 151 which is made of an inorganic material, the organic encapsulation layer 152 made of an organic material and disposed on the first inorganic encapsulation layer 151, and a second inorganic encapsulation layer 153 disposed on the organic encapsulation layer 152. However, aspects of the present disclosure are not limited thereto.

The first inorganic encapsulation layer 151 seals the display area AA and prevents oxygen and moisture from penetrating into the display area AA to protect the light-emitting element 120. The first inorganic encapsulation layer 151 may be disposed not only in the display area AA, but also in the non-display area NA extending from the display area AA, and thus may be disposed to cover the dam 130 of the non-display area NA. The first inorganic encapsulation layer 151 may be made of an inorganic material, for example, silicon nitride (SiNx), silicon oxide (SiOx), silicon oxynitride (SiON), etc. However, aspects of the present disclosure are not limited thereto.

The organic encapsulation layer 152 is disposed on the first inorganic encapsulation layer 151. The organic encapsulation layer 152 may planarize a portion on top of the first inorganic encapsulation layer 151, and may fill cracks that may occur in the first inorganic encapsulation layer 151. When a foreign material is deposited on the first inorganic encapsulation layer 151, the organic encapsulation layer 152 may planarize a portion on top of the foreign material. The organic encapsulation layer 152 may be disposed in the display area AA and in a portion of the non-display area NA extending from the display area AA, and may be disposed inwardly of the dam 130. The organic encapsulation layer 152 may be made of an epoxy-based or acryl-based polymer. However, aspects of the present disclosure are not limited thereto.

The second inorganic encapsulation layer 153 is disposed on the organic encapsulation layer 152. The second inorganic encapsulation layer 153 is in contact with the first inorganic encapsulation layer 151 in an outer area of the display unit 100 such that the second inorganic encapsulation layer 153 together with the first inorganic encapsulation layer 151 may seal the organic encapsulation layer 152. The second inorganic encapsulation layer 153 may be disposed in a portion of the non-display area NA extending from the display area AA. The second inorganic encapsulation layer 153 may be disposed to be in contact with a portion of the first inorganic encapsulation layer 151 disposed in the non-display area NA. The second inorganic encapsulation layer 153 may be made of an inorganic material, for example, silicon nitride (SiNx), silicon oxide (SiOx), silicon oxynitride (SiON), etc. However, aspects of the present disclosure are not limited thereto.

In FIG. 10, the encapsulation portion 150 is shown as including the first inorganic encapsulation layer 151, the organic encapsulation layer 152, and the second inorganic encapsulation layer 153. However, the number of the inorganic encapsulation layers included in the encapsulation portion 150 and the number of the organic encapsulation layers included in the encapsulation portion 150 are not limited thereto.

The touch unit 160 is disposed on the encapsulation portion 150. The touch unit 160 may be disposed in the display area AA including the light-emitting element 120 and may sense a touch input. The touch unit 160 may detect external touch information input thereto using the user's finger or a touch pen. The touch unit 160 may include a first protection layer 161, a second protection layer 162, an organic insulating layer 167, a first touch electrode 164, and a second touch electrode 165.

The first protection layer 161 may be disposed on the encapsulation portion 150. The first protection layer 161 may be in contact with the second inorganic encapsulation layer 153 of the encapsulation portion 150. The first protective layer 161 may be made of inorganic material. For example, the first protective layer 161 may be made of an inorganic material such as silicon nitride (SiNx), silicon oxide (SiOx), silicon oxynitride (SiONx), etc. However, aspects of the present disclosure are not limited thereto.

The first touch electrode 164 is disposed on the first protection layer 161. The first touch electrode 164 is disposed in the non-light-emitting area NEA and on the first protection layer 161. The first touch electrode 164 may include patterns spaced apart from each other and arranged in the X-axis direction and the Y-axis direction. For example, the first touch electrode 164 may include a plurality of patterns spaced apart from each other and arranged in the X-axis direction and a plurality of patterns spaced apart from each other and arranged in the Y-axis direction. The first touch electrode 164 supplies a touch driving signal to drive the touch unit 160. Furthermore, the first touch electrode 164 may transmit touch information detected by the touch unit 160 to a driving IC. The first touch electrode 164 may be in a form of a mesh. However, aspects of the present disclosure are not limited thereto. The first touch electrode 164 may be made of a metal material. However, aspects of the present disclosure are not limited thereto.

The second protection layer 162 may be disposed on the first touch electrode 164 and the first protection layer 161. The second protection layer 162 may prevent short-circuit between patterns of the first touch electrode 164 adjacent to each other.

The second touch electrode 165 may be disposed on the second protection layer 162. The second protective layer 162 may be made of inorganic material. For example, the second protective layer 162 may be made of an inorganic material such as silicon nitride (SiNx), silicon oxide (SiOx), or silicon oxynitride (SiONx). However, aspects of the present disclosure are not limited thereto.

For example, the pad 140 and the second touch electrode 165 may be electrically connected to the circuit film 400 via a conductive adhesive layer 395. However, aspects of the present disclosure are not limited thereto.

The display apparatus according to an aspect of the present disclosure may be applied to a mobile device, a video phone, a smart watch, a watch phone, a wearable device, a foldable device, a rollable device, a bendable device, a flexible device, a curved device, a sliding device, a variable device, an electronic notebook, an e-book, a portable multimedia player (PMP), a personal digital assistant (PDA), a MP3 player, a mobile medical device, a desktop PC, a laptop PC (personal computer), a netbook computer, a workstation, a navigation, a vehicle navigation, a vehicle display apparatus, a vehicle device, a theater device, a theater display apparatus, a television, a wallpaper device, a signage device, a game device, a laptop, a monitor, a camera, a camcorder, and home appliances. In addition, the display apparatus of the present disclosure may be applied to an organic light-emitting lighting apparatus or an inorganic light-emitting lighting apparatus.

The display apparatus according to an aspect of the present disclosure may be described as follows.

A first aspect of the present disclosure provides a display apparatus comprising: a support member; a display panel disposed on the support member; a printed circuit board electrically connected to one side of the display panel; and at least one circuit film having one side and the other side opposite to each other and electrically connected to the display panel and the printed circuit board, respectively, wherein at least a portion of the at least one circuit film is bent toward a rear surface of the display panel, wherein the support member includes at least one extension protruding from a side surface of the display panel and overlapping the circuit film on a rear surface of the circuit film.

In the display apparatus of the first aspect, the display apparatus further comprises a driver chip disposed in rear surface of the display panel, wherein the driver chip is disposed on the rear surface of the circuit film.

In the display apparatus of the first aspect, the extension is bent from one side of the support member toward the rear surface of the display panel.

In the display apparatus of the first aspect, the at least one extension of the support member further includes at least one opening.

In the display apparatus of the first aspect, the at least one extension of the support member includes a plurality of extensions spaced apart from each other.

In the display apparatus of the first aspect, a number of the at least one extension of the support member is equal to a number of the at least one circuit film.

In the display apparatus of the first aspect, a material of the support member and a material of the circuit film are different from each other.

In the display apparatus of the first aspect, a thickness of the support member and a thickness of the circuit film are different from each other.

In the display apparatus of the first aspect, the thickness of the support member is larger than the thickness of the circuit film.

In the display apparatus of the first aspect, the extension of the support member further includes a non-contact portion non-contacting the circuit film.

In the display apparatus of the first aspect, the at least one opening of the extension of the support member has a straight shape.

In the display apparatus of the first aspect, the at least one opening of the extension of the support member has a circular shape.

In the display apparatus of the first aspect, the circuit film includes polyimide.

In the display apparatus of the first aspect, at least one shape of the opening is bent in a direction in which the extension is bent.

In the display apparatus of the first aspect, the support member includes polyethylene terephthalate.

A second aspect of the present disclosure provides a display apparatus comprising: a support member; a display panel disposed on the support member; a printed circuit board electrically connected to one side of the display panel; and at least one circuit film electrically connected to the printed circuit board, wherein a portion of the at least one circuit film is bent, wherein the support member overlaps at least a portion of the circuit film in a protruding area of the circuit film and includes at least one opening.

In the display apparatus of the second aspect, the support member includes at least one extension protruding from a side surface of the display panel.

In the display apparatus of the second aspect, the support member includes a non-contact portion non-contacting the circuit film.

In the display apparatus of the second aspect, the support member includes a bent portion supporting a rear surface of the circuit film.

In the display apparatus of the second aspect, a pad is disposed in a non-display area of the display panel, wherein the pad is electrically connected to the circuit film via a conductive adhesive layer.

It will be apparent to those skilled in the art that various modifications and variations can be made in the display apparatus of the present disclosure without departing from the spirit or scope of the aspects of the present disclosure. Thus, it is intended that the present disclosure covers the modifications and variations of the aspects provided they come within the scope of the appended claims and their equivalents.

What is claimed is:

1. A display apparatus comprising:
a support member;
a display panel disposed on the support member;
a printed circuit board electrically connected to one side of the display panel; and
at least one circuit film having one side and another side opposite to each other and electrically connected to the display panel and the printed circuit board,
wherein the at least one circuit film includes a portion bent toward a rear surface of the display panel, and
wherein the support member includes at least one extension protruding from a side surface of the display panel and overlapping the circuit film on a rear surface of the at least one circuit film.

2. The display apparatus of claim 1, further comprising a driver chip disposed in the rear surface of the display panel,
wherein the driver chip is disposed on the rear surface of the circuit film.

3. The display apparatus of claim 1, wherein the extension is bent from one side of the support member toward the rear surface of the display panel.

4. The display apparatus of claim 1, wherein the at least one extension of the support member further includes at least one opening.

5. The display apparatus of claim 1, wherein the at least one extension of the support member includes a plurality of extensions spaced apart from each other.

6. The display apparatus of claim 1, wherein a number of the at least one extension of the support member is equal to a number of the at least one circuit film.

7. The display apparatus of claim 1, wherein a material of the support member and a material of the at least one circuit film are different from each other.

8. The display apparatus of claim 1, wherein a thickness of the support member and a thickness of the at least one circuit film are different from each other.

9. The display apparatus of claim 8, wherein the thickness of the support member is larger than the thickness of the at least one circuit film.

10. The display apparatus of claim 1, wherein the extension of the support member further includes a non-contact portion non-contacting the at least one circuit film.

11. The display apparatus of claim 4, wherein the at least one opening of the extension of the support member has one of a straight shape and a circular shape.

12. The display apparatus of claim 1, wherein the at least one circuit film includes polyimide.

13. The display apparatus of claim 11, wherein at least one shape of the opening is bent in a direction in which the extension is bent.

14. The display apparatus of claim 1, wherein the support member includes polyethylene terephthalate.

15. A display apparatus comprising:
a support member;
a display panel disposed on the support member;
a printed circuit board electrically connected to one side of the display panel; and
at least one circuit film electrically connected to the printed circuit board, wherein a portion of the at least one circuit film is bent,
wherein the support member overlaps at least a portion of the circuit film in a protruding area of the at least one circuit film and includes at least one opening.

16. The display apparatus of claim 15, wherein the support member includes at least one extension protruding from a side surface of the display panel.

17. The display apparatus of claim 15, wherein the support member includes a non-contact portion non-contacting the at least one circuit film.

18. The display apparatus of claim 15, wherein the support member includes a bent portion supporting a rear surface of the at least one circuit film.

19. The display apparatus of claim 15, wherein a pad is disposed in a non-display area of the display panel, and
wherein the pad is electrically connected to the at least one circuit film via a conductive adhesive layer.

20. A display apparatus comprising:
a support member;
a display panel disposed on the support member;
a printed circuit board disposed under the display panel; and
a circuit film having one side electrically connected to one side of the display panel and another side electrode connected to the printed circuit board,
wherein the extension is bent from one side of the support member to the printed circuit board, and
wherein at least a part of the circuit film extends along the extension part of the plate and is supported by the extension.

21. The display apparatus of claim 20, wherein the support member includes an extension part including a bent portion, a contact portion and a non-contact portion non-contacting the circuit film.

22. The display apparatus of claim 21, wherein the bent portion and the contact portion contact and support the circuit film.
